(19) United States
(12) Patent Application Publication
(10) Pub. No.: US 2012/0314895 A1
(43) Pub. Date: Dec. 13, 2012

(54) SHEATH TO MASK ELECTRICAL CONDUCTOR

(76) Inventor: Charles M. Siebenberg, New York, NY (US)

(21) Appl. No.: 13/473,039

(22) Filed: May 16, 2012

Related U.S. Application Data
(63) Continuation of application No. 61/486,983, filed on May 17, 2011.

(51) Int. Cl. H04R 1/02; F21V 21/00; G06K 19/077; H01B 7/00; H05K 7/02

(52) U.S. Cl. 381/334; 174/110 R; 361/679.01; 235/492; 362/249.02

(57) ABSTRACT

A portable, flexible cover connected between a source of signals such as an MP3 player and headphones, the flexible cover comprising a substantially flat and flexible surface encapsulating a conductor yet substantially resting on a surface or on the body of a wearer and have a design to mask the conductor and minimize tangling thereof.

### RELATED APPLICATION

This application claims priority of U.S. Provisional patent application Ser. No. 61/486,983, filed May 17, 2011, the contents of which is incorporated herein.

### BACKGROUND OF THE INVENTION

1. Field of Invention

The present invention relates to flexible conductor covers for electronics, one use of which is with portable music devices.

2. Description of the Prior Art

Electrical and electronic devices such as personal devices, telephones, even desk lamps, usually have loose conductors between a source of sound or data or a wall socket and the device receiving such input. Such loose conductors are not only unsightly, they can often get snagged, pull the electronic devices loose or otherwise become entangled.

Fixed conductor covers already exist, primarily for physical permanent attachment to a floor or wall to mask or hide conductors, preventing their loose hanging and also preventing potential tangling, tripping or the like. These prior art conductor covers are rigid and are generally physically fixed to a flat surface under which the conductors, cables or power lines are hidden.

There exists a need for conductor covers, especially with portable music devices and the like, so as to cover loose, dangling wires in an efficient manner, allowing adaptability of the cover to a surface or to an environment, Such a flexible conductor cover may also be of unique artistic design to both enhance the masking of the conductor, the general attractiveness of the cover and the functionality of adapting the cover to any suitable environment whether large or small. The cover of this invention is not intended to be physically permanently attached to a fixed flat device, but is intended to be used as desired in random environments where covering such conductors is desirable. This invention is desired as directed to one specific embodiment, that is portable music devices, but the flexible, adaptable conductor cover may be used in many other environments, as will be briefly described within this specification.

Portable music devices, such as iPods and MP3 players, are ubiquitous in today's world. Rarely can one walk a few feet on a crowded street, or ride public transportation, without seeing someone listening to such a device.

As is well known, one listens to such device using a set of earphones, which comprise fine, insulation-covered wires and earphones having so-called ear buds which lodge in the ear. These wires are rather delicate, hang from the body, and easily catch on clothing, buttons, and other objects, and are susceptible to tangling easily pulling the ear buds out of the ear.

As such, there has long been a need for a means to protect these wires from possible damage. In addition, not only do they easily tangle because of the thinness and free dangling of such wires, but such thinness can be eliminated and such cables will have enhanced functionality and an enhanced appearance.

An object of this invention is to provide a sheath or covering for electrical conductors especially used with portable music devices which minimizes the susceptibility of such conductors to dangling or loosely hanging and becoming easily tangled or caught.

Another object of this invention is to provide such a sheath or covering which itself masks the conductor and provides a suitable and attractive appearance thereby enhancing the overall experience of utilizing portable music devices.

Still another object of this invention is to provide such a sheath or covering which may include active electronic elements thereby not only providing conductivity but also independent electrical functionality enhancing the desirability of such a cover.

Another object of this invention is to provide such a sheath or covering which is portable, flexible, of sufficient mass to rest on a flat surface or to conform and rest on a portion of the body but adaptable to be easily lifted, removed and otherwise placed in other environments.

Yet another object of this invention is to provide such a sheath which may be worn as an article of clothing which provides both functionality and concurrently independently provides an attractive appearance.

Other objects, advantages and features of this invention will become more apparent from the following description.

### SUMMARY OF THE INVENTION

The above objects are accomplished by providing a sheath or covering for an electrical conductor which is flexible, susceptible to being of an attractive design, portable, so as to be easily lifted from wherever it might be currently covering conductors, and otherwise serving to connect an electrical signal entering from one end of the cover and exiting from the other end of the cover. In one specific embodiment, the cover covers a conductor carrying signals between a sound source and earphones, with the sheath comprising bulk and size thereby converting the prior art thin wire to a planar surface susceptible of an appearance which hides the conductor carrying capability of the sheath and enables the sheath to substantially securely allow the conductor to operate without its easily being tangled or caught, thereby ensuring continuous conductor operation.

One approach to creating such a sheath is to encapsulate an electronic wire within such a sheath or covering, with the sheath having flexibility and plasticity so as to be able to drape on the body of the wearer. Another alternative is forming such a cover or sheath out of flexible electronics, allowing for conductivity, sheath formation and active elements.

In accordance with the teachings of this invention, the cover is formed with a silhouette and is flexible enough to drape on the body of the wearer eliminating easy tangling and catching. In addition, such silhouettes are susceptible to being formed of various shapes and symbols enhancing the overall appearance and functionality of ubiquitous portable music devices.

In further accordance with the teachings of this invention, this portable, flexible conductor cover or sheath may be used in any environment suitable for ease of utilization, such as on a desk, a floor, by musicians, or otherwise where easily applicable.

The invention accordingly comprises the features of construction, combinations of elements, and arrangements of parts and processes, which will be exemplified in the constructions and processes as hereinafter set forth, and the scope of the invention will be indicated in the claims.

Additionally, such sheaths or covers may comprise conductors and integrated active elements which are integrally formed in such flex circuits to enable such covers or sheaths to have independent functionality, such as carrying RFID chips, housing LEDS's, or comprising a flat LCD screen. Other embodiments and features will be described or will be apparent to one of ordinary skill in the art.

### BRIEF DESCRIPTION OF THE DRAWINGS

FIG. 1 is a plan view of the prior art set of earphones;

FIGS. 2A and 2B are front plan views of a first embodiment of the sheath of the present invention used with portable music devices;

FIG. 3 is a front plan view of a second embodiment of the sheath of this invention being worn;

FIG. 4 is a front plan view of a third embodiment of the sheath;

FIG. 5 is a front plan view of a fourth embodiment of this invention;

FIG. 6 is a cross-sectional view of one embodiment of the sheath or cover of this invention.

FIG. 7 is a front plan view of a fifth embodiment of this invention in which a screen is enclosed as part of the cover.

### DETAILED DESCRIPTION OF THE PREFERRED EMBODIMENT

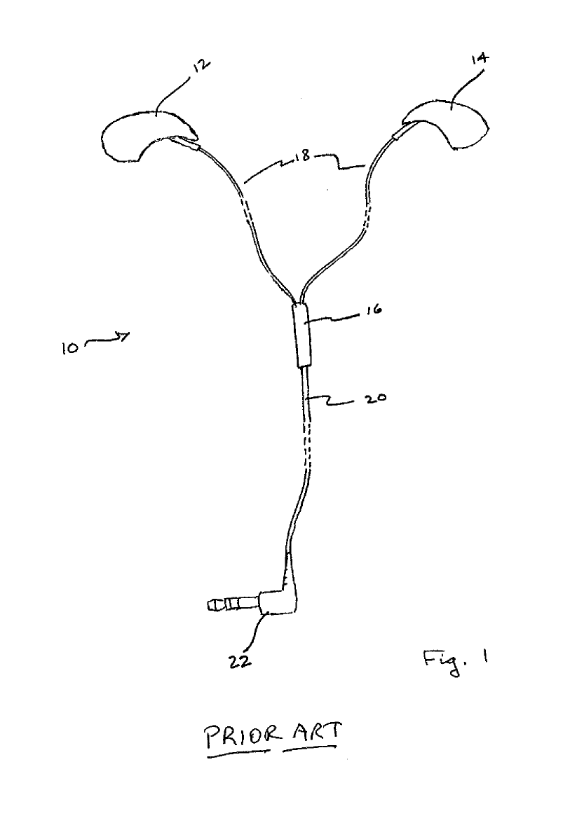

Turning now to the figures, FIG. 1 is a plan view of a prior art portable music device 10 and cables 16, 18 and 20 for use with such a portable music device.

While this invention is described with relationship to portable music devices, it is understood the general teaching of a flexible, portable conductor cover susceptible of independent, unique esthetic design and functionality represents the underlying invention set forth herein.

Referring again to FIG. 1, the prior art portable music device includes a right earphone 12 and a left earphone 14, both connected to a branching point 16 by insulated wires or conductors 18. From the branching point 16, the two wires 18 are joined into a common wire or conductor 20 which is connected to a plug 22 of a design which is universally compatible with portable music devices of many manufacturers.

Referring back to FIG. 1, wires 18 and 20 are drawn with dashed-line segments to suggest that the relative lengths of wires 18 and 20 may vary. Typically, wire 20 may be longer than wires 18, which basically leads to branching point 16. But this need not be the case, as cable 20, it will be seen, may be quite short in some embodiments of the present invention.

It will be recalled that one purpose of the present invention is to protect and provide additional bulk to cables 18, 20, between plug 22 and the earphones thereby making them less prone to tangling and inadvertently pulling the earphones out of the ears.

Generally this is accomplished by the present invention providing a sheath or cover for branch point 16 and conductors 18 with the cover masking the branch point and conductors yet providing sufficient bulk and surface to partially drape on the user and protect the conductors from snagging, yet also providing an attractive design which also masks its functionality. One might even think there are no wires between the sound source and earphones.

One way to create or produce such a sheath or cover is to utilize conventional flexible circuits which are generally passive conductors formed of a thin copper layer sandwiched between insulating layers forming a substantially flat assembly. Flexible circuits are described at Wikipedia.com.

The present invention provides such a flexible cover or sheath which essentially comprises conductors carrying electrical signals between a sound source and earphones which replace all or a portion of the thin cables 16 and 18 shown in FIG. 1. The flexible cover or sheath of the present invention is provided with sufficient size and bulk and is thin enough to rest or be draped on the body of the user thereby conforming the cable to the body and minimizing the general loose hanging, unmanageable cables shown in FIG. 1, which often become tangled, dislodged and are unwieldy.

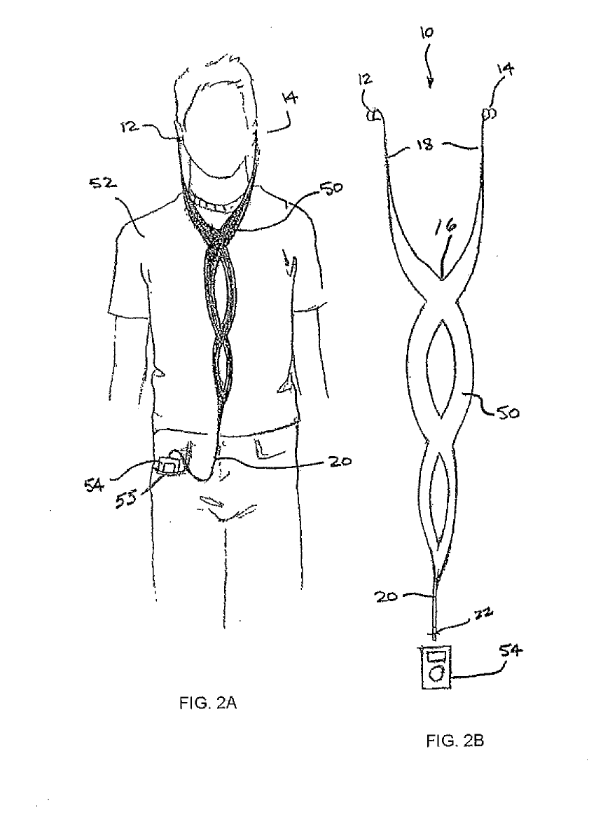

Turning to FIGS. 2A and 2B, there is provided a front perspective view of the cover or sheath 50 of this invention. This embodiment of the present invention includes a set of earphones 12 and 14 connected to the conductors cove red with cover 50. Earphones 12 and 14 are disposed within the respective ears of subject 52 in FIG. 2A. A portable music device 54 is connected to plug 22 and the end of wire 20, and may conveniently be disposed within a pocket 55, as shown. It will be understood that the conductor 20 continues within cover 50 to branching point 16, where it splits into conductors 18. Conductor 20 connects with earphones 12 and 14 with either an encapsulated conductor sandwiched between outer layers or as part of the conductive layer described above regarding flexible circuits.

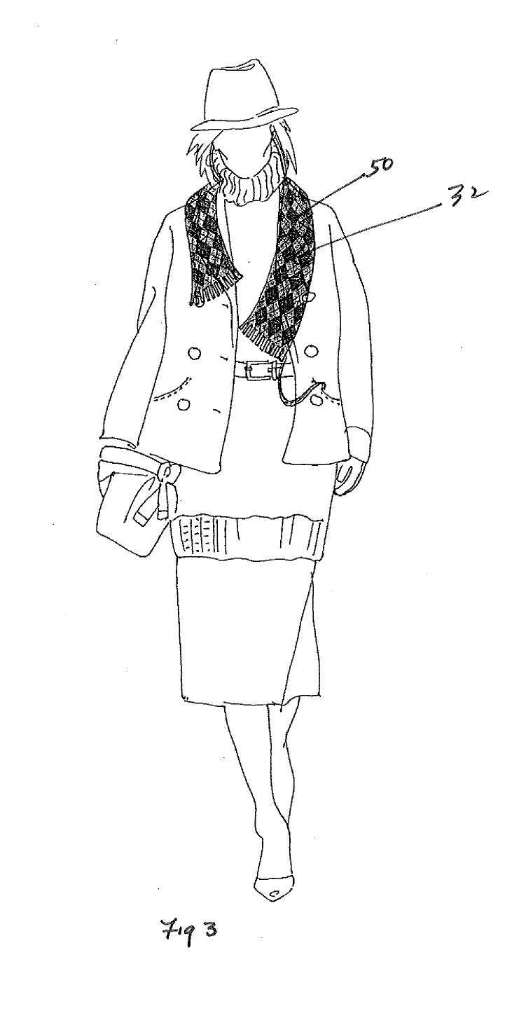

FIGS. 3, 4 and 5 are front plan perspective views of alternative embodiments of the present flexible conductor sheath or cover of this invention.

FIG. 3 illustrates the flexible cover 50 having the appearance of a common article of clothing, such as a scarf. The outer layers of the flexible cover may comprise a fabric having a pattern and scarf shape 32 as shown in FIG. 3, thereby substantially masking the conductor yet allowing it to conveniently drape on the body of the wearer. This cover 32 substantially eliminates the loose hanging manner of the prior art cable of FIG. 1. Earphones 12 and 14 are connected to the scarf 32 but are substantially unseen.

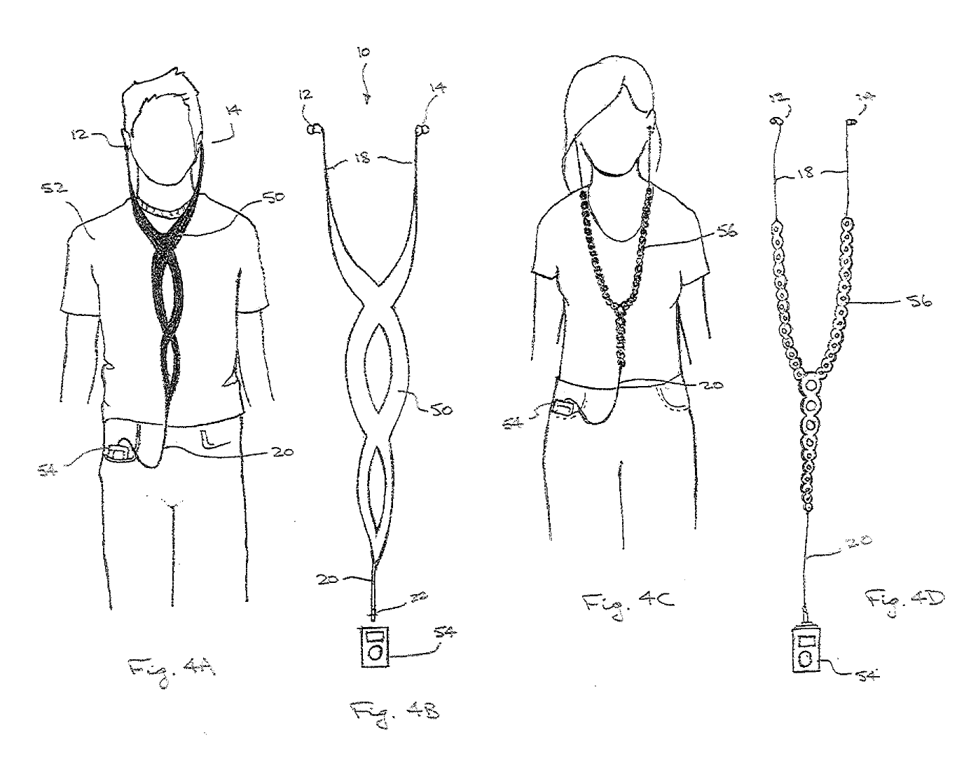

FIG. 4 is a front perspective view of another embodiment of the present invention in which the flexible cover 50 may be formed to be a well known symbol, such as a Coca-Cola bottle 42. This symbol 42 is in a flat form with large bulk and its otherwise flat structure will rest against the chest of the wearer, thereby minimizing the likely disengagement of the conductors from the headphone, The cover has wire 20 extending to the music source and conductors 18 extending to earphones.

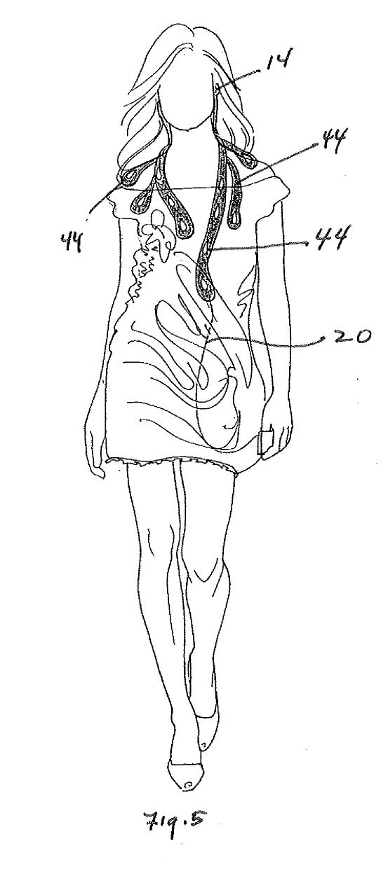

FIG. 5 is yet another embodiment of the present invention in which the conductor between the sound source and headphones is carried in but one of a plurality of decorative thin tail like structures 44 thereby further masking the conductor and ensuring minimization of inadvertent catching and tangling of the conductor.

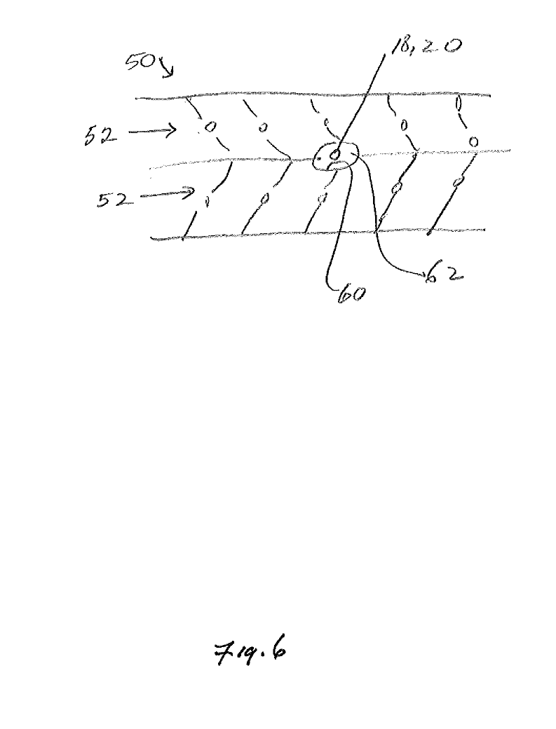

FIG. 6 is a cross-sectional view of one approach to produce sheath or cover 50. Covering 50 is molded from a flexible, pliable, and resilient polymeric resin material 52, such as a silicone rubber. Covering 50 is molded with a passage 60 which is accessible through a gap 62. When wires 18, 20 are disposed within the covering 50, they are pressed through gap 62 into passage 60. Gap 62 may subsequently be sealed with an adhesive, through the use of heat, or through other means. Alternatively, where the gap 62 is sufficiently narrow, where, for instance, the two sides of the gap 62 are in contact with one another, wires 18, 20 may be held within passage 60 mechanically without any sealing means. This embodiment allows the cover or sheath 50 to be formed of any desired ornamental appearance including those shown in FIGS. 2-5.

The field of flexible circuits is well known and continuing to develop and encompasses flat circuits having a flat cable or flat band appearance in which both active and passive elements may be integrated to provide suitable electrical circuits.

The present invention may incorporate flat LCD's to form a screen on the surface of the cover or sheath. Multek is a source of flat LCD displays as is Fujitsu which provides flat and flexible LCD screens.

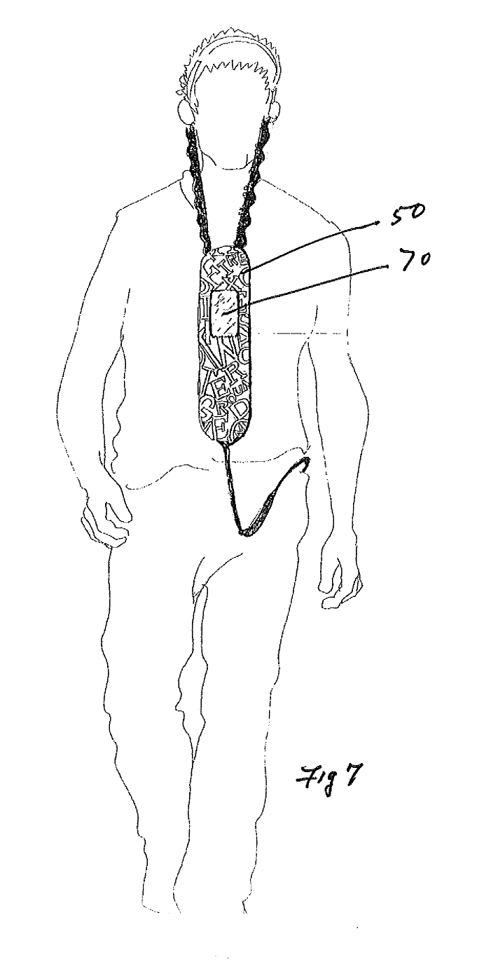

FIG. 7 is a front plan view of another embodiment of this invention in which the cover or sheath 50 includes a screen 70. If the portable music device includes video, the screen may show such video while the portable music device is operating. Additionally, with portable personal devices increasing in use, diversity and applications, one could watch his/her favorite DVD, computer stored video, or any other desired video, with the active circuits encapsulated within cover sheath 50 having screen 70 shown in FIG. 7.

Additionally, flat LED's can be employed as a visual display or manually controlled volume control. Such flat LED's are available from Samsung and is known as the Flexible OLED screen. Sony also offers an LED screen known as a flexible full color paper screen.

An RFID device may be integrated within the cover 50 of the present invention so that a user's unique identifying codes may be carried in an inconspicuous yet ubiquitously available manner. The RFID codes could be limited to specific information concerning music or other related information, but could also include personal identifying information such as bank codes, etc., to enable the flat cover or sheath of this invention to provide a multitude of uses in a hidden manner, especially as shown in FIGS. 3-5.

Additionally, a mini cellphone having a camera, such as a Nokia N97 could be incorporated in cover 50.

The cover 50 of the present invention is intended to bear or rest on the body of a person and be located between a source of sound and the earphones. On the other hand, the flexible circuit (cover) of the present invention could also be formed as a wristband and carry the above identified active elements and or RFID chips.

Lithium batteries are becoming increasingly thin, flat and flexible, and such batteries can be integrated within the cover of this invention to provide suitable power for active elements integrated therein. Such a flexible battery is available from Solicare Inc. and comprises an ultrathin flexible lithium battery sold under the Flexion brand.

One common flexible circuit construction is a flexible foil which laminates thin copper strips between two layers of PET. In accordance with the teachings of this invention, thin outer layers may be attached to the PET layers and such outer layers may comprise fabric or suitable designs thereby giving the appearance of an item of clothing rather than an electronic cable. An example of such material is that provided by Shawmut Corp. and is headliner fabric suitable to being bonded to conventional flexible circuits forming cover 50 of this invention.

As described above, this invention utilizes flexible electronics also known as flex circuits, which is a technology for assembling electronic circuits by mounting such circuits on flexible plastic substrates, such as polyimide, PEEK, or transparent conductive polyester. Flex circuits can also be screen printed silver circuits on polyester. The present invention primarily uses flexible foil circuits to form cables by laminating very thin copper strips between two layers of PET. These PET layers, typically 0.05 mm thick are coated with an adhesive which is thermosetting and will be activated during the lamination process.

The present invention takes advantage of the size, bulk and thinness of flex circuits by providing conductors to connect a sound source to earphones with the flex circuits or the flexible cover actually resting on the body of the wearer. This largely eliminates the type of kinking, twisting or other undesirable aspects of the loose hanging wires shown in FIG. 1.

While the present invention is shown with an embodiment of portable music players, the beneficial applications of such conductors may also be employed in other environments. These could include USB cables, guitar and keyboard cables, microphone and speaker cables, RCA connector cables, power lines, desk set telephones and lamps, and the like.

In summary, the present invention is directed to a flexible, portable cover or sheath for conductors susceptible of individual esthetic design and appearance having the conductor connected to a source of signal, whether power, video, audio or the like at one end and connected to the device to receive such a signal, whether earphones, a desk lamp, an acoustic guitar or any other environment in which the portable, flexible conductor cover of this invention can serve to both mask the conductors, prevent such conductors from being tangled or otherwise being unwieldy and independently provide an attractive appearance further masking the functionality of such cover or sheath.

It should be understood that the preferred embodiment was described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly legally and equitably entitled.

What is claimed is:

1. A cover for an electrical conductors, said conductor located between a source of signals and a device to be operated by said signals, employed to carry sound between a personally carried sound source and speakers carried within a user's ear, said cover comprising:
a portable and flexible cover comprising said conductor sandwiched between insulating layers,
said flexible cover having a size and bulk substantially greater than the conductor carried therein and having a flexibility and bulk permitting said flexible cover to rest on a surface, yet be instantly removed therefore when desired,
said flexible cover being formed of a suitable attractive appearance substantially masking its function.

2. A flexible cover according to claim 1, wherein said flexible cover is formed in the shape of a well known symbol, formed as a substantially flat, flexible cover.

3. A flexible cover according to claim 1, wherein said flexible cover comprises flexible electronics.

4. A flexible cover according to claim 3, wherein said flexible circuit comprises active and passive elements.

5. A flexible cover according to claim 4, wherein said flexible circuit comprises RFID chips.

6. A flexible cover according to claim 4, wherein said flexible conductor comprises a screen comprising flat LED devices.

7. A flexible cover according to claim 4, wherein said flexible conductor comprises a screen comprising LCD devices.

8. A flexible cover according to claim 4, wherein said flexible circuit comprises a substantially flat source of power housed within said cover to power the active elements integrated therein.

9. A cover for an electrical conductors as in claim 1, wherein said device comprises personal speakers such as a headphone and said source is a sound source,
said flexible cover having a size and bulk substantially greater than the conductor carried therein and having a flexibility and bulk permitting said flexible cover to rest on a surface, yet be instantly removed therefore when desired,
said flexible cover being formed of a suitable ornamental appearance substantially masking its function.

10. A flexible cover according to claim 9, wherein said flexible cover is formed in the shape of a well known symbol, formed as a substantially flat, flexible cover.

11. A flexible cover according to claim 9, wherein said flexible cover comprises an article of clothing worn about the neck, said article of clothing comprising fabric-like material and carrying said conductor between said source of sound and said speakers.

12. A flexible cover according to claim 9, wherein said flexible cover comprises flexible electronics.

13. A flexible cover according to claim 11, wherein said flexible circuit comprises active and passive elements.

14. A flexible cover according to claim 9, wherein said flexible circuit comprises RFID chips.

15. A flexible cover according to claim 9, wherein said flexible conductor comprises a screen comprising flat LED devices,

16. A flexible cover according to claim 11, wherein said flexible conductor comprises a screen comprising LCD devices.

17. A flexible cover according to claim 11, wherein said flexible circuit comprises a substantially flat source of power housed within said cover to power the active elements integrated therein.
